(19) United States
(12) Patent Application Publication
(10) Pub. No.: US 2026/0014667 A1
(43) Pub. Date: Jan. 15, 2026

(54) CARRIER FOR POLISHING WORKPIECES WITH FLATS OR VOIDS

(71) Applicant: Axus Technology, LLC, Chandler, AZ (US)

(72) Inventors: Daniel Ray Trojan, Chandler, AZ (US); John Kevin Shugrue, Phoenix, AZ (US); William Manfred Daschbach, Gilbert, AZ (US)

(21) Appl. No.: 18/995,709

(22) PCT Filed: Jul. 24, 2023
(86) PCT No.: PCT/US2023/028499

§ 371 Date: Jan. 16, 2025

Related U.S. Application Data
(60) Provisional application No. 63/369,490, filed on Jul. 26, 2022.
(60) Provisional application No. 63/369,917, filed on Jul. 29, 2022.

(51) Int. Cl. B24B 37/30; H01L 21/687

(52) U.S. Cl. CPC B24B 37/30; H01L 21/68757

(57) ABSTRACT

Carriers for polishing workpieces with flats or voids are provided. In one aspect, a substrate carrier head for a chemical mechanical planarization (CMP) system include a carrier body comprising an aperture configured to receive a wafer and a membrane having a first surface configured to contact a surface of the wafer and a second surface opposing the first surface, the membrane having a primary zone and a secondary zone. The substrate carrier head further includes a membrane cavity formed along the second surface and configured to apply pressure to the membrane within the primary zone, and a membrane support plate configured to support the secondary zone of the membrane.

### INCORPORATION BY REFERENCE TO ANY PRIORITY APPLICATIONS

This application claims the benefit of U.S. Provisional Patent Application No. 63/369,490, filed Jul. 26, 2022, and U.S. Provisional Patent Application No. 63/639,917, filed Jul. 29, 2022, the disclosure of each of which is incorporated herein by reference in its entirety and for all purposes. Any and all applications for which a foreign or domestic priority claim is identified in the PCT Request as filed with the present application are hereby incorporated by reference under 37 CFR 1.57.

### BACKGROUND

### Field

This disclosure is generally related to carriers for polishing workpieces, and more specifically, to a system and apparatus for improving chemical mechanical planarization (CMP) performance for the planarization of thin films.

### Description of the Related Technology

CMP systems are designed to planarize the surface of a wafer in order to provide a sufficiently planar surface when manufacturing semiconductor chips. As the processing steps for manufacturing semiconductor chips become more complex and/or the chip design is miniaturized, the tolerances for planarizing the surface of a wafer may become more precise. Thus, it can be desirable to improve the uniformity of planarization which can involve identifying and reducing sources of uneven removal rates.

### SUMMARY OF CERTAIN INVENTIVE ASPECTS

For purposes of summarizing the disclosure and the advantages achieved over the prior art, certain objects and advantages of the disclosure are described herein. Not all such objects or advantages may be achieved in any particular embodiment. Thus, for example, those skilled in the art will recognize that the invention may be embodied or carried out in a manner that achieves or optimizes one advantage or group of advantages as taught herein without necessarily achieving other objects or advantages as may be taught or suggested herein.

One aspect of the disclosed technology is a substrate carrier head for a chemical mechanical planarization (CMP) system, comprising: a carrier body comprising an aperture configured to receive a wafer; a membrane having a first surface configured to contact a surface of the wafer and a second surface opposing the first surface, the membrane having a primary zone and a secondary zone; a membrane cavity formed along the second surface and configured to apply pressure to the membrane within the primary zone; and a membrane support plate configured to support the secondary zone of the membrane.

In some embodiments, the secondary zone of the membrane is isolated from the pressure applied to the primary zone of the membrane.

In some embodiments, the membrane is further configured for substantially continuous contact with the wafer.

In some embodiments, the primary zone of the membrane comprises a plurality of sub-zones, the substrate carrier head further comprising a processor configured to control a pressure applied to each of the sub-zones independently.

In some embodiments, the wafer comprises a flat edge that forms a void when the wafer is held by the carrier body, wherein a width of the secondary zone is larger than the void to prevent the membrane from filling the void.

In some embodiments, the membrane support plate has an annular shape and is configured to control pressure applied to the secondary zone of the membrane.

In some embodiments, the substrate carrier head is compatible with a membrane control CMP System.

In some embodiments, the substrate carrier head further comprises: an inner plate; and an outer plate, wherein the membrane further comprises an internal ridge secured between the inner plate and the outer plate and configured to isolate the primary zone from the secondary zone.

In some embodiments, the substrate carrier head further comprises: a membrane backing ring arranged above the outer plate and securing the membrane in place.

In some embodiments, the substrate carrier head further comprises: an adhesive that adheres the secondary zone of the membrane to the membrane support plate.

Another aspect is a chemical mechanical planarization (CMP) system, comprising: a substrate carrier head, comprising: a carrier body comprising an aperture configured to receive a wafer; a membrane having a first surface configured to contact a surface of the wafer and a second surface opposing the first surface, the membrane having a primary zone and a secondary zone; a membrane cavity formed along the second surface and configured to apply pressure to the membrane within the primary zone; and a membrane support plate configured to support the secondary zone of the membrane; and a processor configured to control pressure applied to the membrane via the membrane cavity.

In some embodiments, the secondary zone of the membrane is isolated from the pressure applied to the primary zone of the membrane.

In some embodiments, the membrane is further configured for substantially continuous contact with the wafer.

In some embodiments, the primary zone of the membrane comprises a plurality of sub-zones, the substrate carrier head further comprising a processor configured to control a pressure applied to each of the sub-zones independently.

In some embodiments, the wafer comprises a flat edge that forms a void when the wafer is held by the carrier body, wherein a width of the secondary zone is larger than the void to prevent the membrane from filling the void.

In some embodiments, the membrane support plate has an annular shape and is configured to control pressure applied to the secondary zone of the membrane.

In some embodiments, the substrate carrier head is compatible with a membrane control CMP System.

In some embodiments, the substrate carrier head further comprises: an inner plate; and an outer plate, wherein the membrane further comprises an internal ridge secured between the inner plate and the outer plate and configured to isolate the primary zone from the secondary zone.

In some embodiments, the substrate carrier head further comprises: a membrane backing ring arranged above the outer plate and securing the membrane in place.

In some embodiments, the substrate carrier head further comprises: an adhesive that adheres the secondary zone of the membrane to the membrane support plate.

Yet another aspect is a method of isolating a primary zone of a membrane from a secondary zone of a membrane, comprising: receiving a wafer in an aperture of a carrier body, the carrier body comprising a membrane having a first surface configured to contact a surface of the wafer and a second surface opposing the first surface, the membrane having a primary zone and a secondary zone; applying pressure to the primary zone of the membrane via a membrane cavity formed along the second surface of the membrane; and supporting the secondary zone of the membrane with a support plate.

In some embodiments, the method further comprises: isolating the secondary zone of the membrane from the pressure applied to the primary zone of the membrane.

In some embodiments, the membrane is further configured for substantially continuous contact with the wafer.

All of these embodiments are intended to be within the scope of the invention herein disclosed. These and other embodiments will become readily apparent to those skilled in the art from the following detailed description of the preferred embodiments having reference to the attached figures, the invention not being limited to any particular preferred embodiment(s) disclosed.

### BRIEF DESCRIPTION OF THE DRAWINGS

The above, as well as additional objects, features and advantages of the present inventive concept, will be better understood through the following illustrative and non-limiting detailed description of embodiments of the present invention, with reference to the appended drawings. In the drawings like reference numerals will be used for like elements unless stated otherwise.

FIG. 1 is a schematic illustration of a chemical mechanical planarization system for treating a polishing pad.

FIG. 2 is a view of the chemical mechanical planarization system of FIG. 1, showing a substrate held by the substrate carrier in a loading position.

FIG. 3 is a partial cross-sectional view of a substrate carrier head which may be included as a part of the substrate carrier illustrated in FIGS. 1 and 2.

FIGS. 4A-4D illustrate an embodiment of a wafer which can experience uneven planarization in accordance with aspects of this disclosure.

FIG. 5A provides a cross-section of the carrier and wafer to illustrate the membrane filling a void created by the flat of the wafer in accordance with aspects of this disclosure.

FIG. 5B is a close up view of the area surrounding the void shown in FIG. 5A.

FIG. 6A shows process results with the effects seen in the large range numbers in non-uniformity due to the burning the flat phenomenon.

FIG. 6B shows the range numbers for the process results when the effects of burning the flat are reduced or eliminated.

FIG. 7 provide another view of the substrate carrier head including the membrane and the IT zone.

FIG. 8 is a cross-sectional view of a rigid back style substrate carrier head in accordance with aspects of this disclosure.

FIGS. 9A and 9B illustrate a substrate carrier head having a sealed IT zone in accordance with aspects of this disclosure.

FIGS. 10A and 10B illustrate a substrate carrier head having a gimbaling apparatus in accordance with aspects of this disclosure.

FIGS. 11A and 11B illustrates another embodiment of a substrate carrier head according to aspects of this disclosure.

FIG. 12 is another embodiment of a substrate carrier head according to aspects of this disclosure.

### DETAILED DESCRIPTION

Although the following text sets forth a detailed description of numerous different embodiments of the invention, it should be understood that the legal scope of the invention is defined by the words of the claims set forth at the end of the patent. The detailed description is to be construed as exemplary only and does not describe every possible embodiment of the invention since describing every possible embodiment would be impractical, if not impossible. Numerous alternative embodiments could be implemented, using either current technology or technology developed after the filing date of this patent, which would still fall within the scope of the claims defining the invention.

### Chemical Mechanical Planarization (CMP)

The adoption and use of chemical mechanical planarization (CMP) for the planarization of thin films in the manufacture of semiconductor ICs, MEMS devices, and LEDs, among many other similar applications, is common among companies manufacturing “chips” for these types of devices. This adoption includes the manufacture of chips for mobile telephones, tablets and other portable devices, plus desktop and laptop computers. The growth in nanotechnology and micro-machining holds great promise for ever-widespread use and adaptation of digital devices in the medical field, in the automotive field, and in the Internet of Things (the “IoT”). Chemical mechanical planarization for the planarization of thin films was invented and developed in the early 1980's by scientists and engineers at the IBM Corporation. Today, this process is widespread on a global basis and is one of the truly enabling technologies in the manufacture of many digital devices.

Integrated circuits are manufactured with multiple layers and alternating layers of conducting materials (e.g., copper, tungsten, aluminum, etc.), insulating layers (e.g., silicon dioxide, silicon nitride, etc.), and semiconducting material (e.g., polysilicon). A successive combination of these layers is sequentially applied to the wafer surface, but because of the implanted devices on the surface, topographical undulations are built up upon the device structures, as is the case with silicon dioxide insulator layers. These unwanted topographical undulations are often flattened or “planarized” using CMP, before the next layer can be deposited, to allow for proper interconnect between device features of ever decreasing size. In the case of copper layers, the copper is deposited on the surface to fill contact vias and make effective vertical paths for the transfer of electrons from device to device and from layer to layer. This procedure continues with each layer that is applied (usually applied by a deposition process). In the case of multiple layers of conducting material (multiple layers of metal), this could result in numerous polishing procedures (one for each layer of conductor, insulator, and semiconductor material) in order to achieve successful circuitry and interconnects between device features.

During the CMP process, the substrate or wafer is held by a wafer carrier which is rotated and pressed, generally via a resilient membrane within the wafer carrier, against the polishing platen for a specified period of time. CMP wafer carriers typically incorporate components for precision polishing of generally flat and round workpieces such as silicon wafers and/or films deposited on them on the process head. These components include: 1) the resilient membrane, with compressed gas applied to the top surface or back side of the membrane; said pressure is then transmitted via the membrane to the top surface or back side of the workpiece in order to effect the material removal during CMP; 2) one or more rigid support components which provide means for: fastening the membrane to its mating components, holding the membrane to its desired shape and dimension, and/or clamping the membrane to provide a sealed volume for sealing and containing the controlled gas pressure.

During the process, slurry is applied onto the rotating polishing pad via through a fluid control device, such as a metering pump or mass-flow-control regulator system. The slurry can be brought to the polishing platen in a single-pass distribution system. For better performance, the slurry particles in their media should be distributed evenly between the rotating wafer, and the rotating polishing pad/platen.

A force is applied to the backside of the wafer by the wafer carrier membrane to press it into the pad and both may have motion to create a relative velocity. The motion and force leads to portions of the pad creating abrasion by pushing the abrasive against the substrate while it moves across the wafer surface. The corrosive chemicals in the slurry alter the material being polished on the surface of the wafer. This mechanical effect of abrasion combined with chemical alteration is called chemical mechanical planarization or polishing (CMP). The removal rate of the material can be easily an order of magnitude higher with both the chemical and mechanical effects simultaneously compared to either one taken alone. Similarly, the smoothness of the surface after polishing is improved by using chemical and mechanical effects together.

During the polishing process, material such as copper, a dielectric, or polysilicon is removed from the surface of the wafer. These microscopic particles either remain in suspension in the slurry or become embedded in the polishing pad or both. These particles cause scratches on the surface of the film being polished, and thus catastrophic failures in the circuitry rendering the chip useless, thus becoming a major negative effect upon yield.

Yield is the driving force in determining success at the manufacturing level for many products including integrated circuits, MEMS, and LEDs. The surface quality tolerances for a CMP process within semiconductor manufacturing facilities (“fabs”) and foundries are measured in nanometers and even Angstroms. The ability to remove material as uniformly as possible from the surface of a wafer or film during CMP is important. Therefore, carrier design technology is constantly evolving toward improving this capability. Small non-uniformities in the flatness of a wafer that has been processed in a CMP system can result in decreased yield and increased waste. Non-uniformities or pressure differentials across the diameters of the wafer carrier and the process pad can cause wafer breakage. The accumulated costs of manufacturing a solid state device are together termed the “Cost-of-Ownership” (CoO) and this term is also applied to each of the required manufacturing steps. The CoO of the CMP process is one of the highest CoO figures in the 500 to 800 individual manufacturing steps required to make a semiconductor “chip” and its associated digital device.

The disclosed technology will be described with respect to particular embodiments and with reference to certain drawings. The disclosure is not limited thereto but only by the claims. The drawings described are only schematic and are non-limiting. In the drawings, the size of some of the elements may be exaggerated and not drawn to scale for illustrative purposes. The dimensions and the relative dimensions do not necessarily correspond to actual reductions to practice of the disclosure.

### CMP Systems

FIG. 1 is a schematic illustration of a chemical mechanical planarization system 100 for treating a polishing pad 110. System 100 can include a wafer carrier 150 configured to hold and process a wafer. It will be understood that the term “wafer” as used herein may refer to a semiconductor wafer (e.g., circular), but can more broadly encompass other types of substrates with different shapes which are processed by polishing or planarizing equipment, such as CMP equipment. Thus, in the following description, the terms “wafer” and “substrate” may be used interchangeably, unless the context clearly relates to only one of a “wafer” or “substrate” in particular. In the illustrated embodiment, the substrate carrier 150 is in a processing (e.g., lower) position, holding the substrate (not shown) against a polishing pad 110 with a membrane (not shown). The polishing pad 110 can be positioned on a supporting surface, such as a surface of a platen 120.

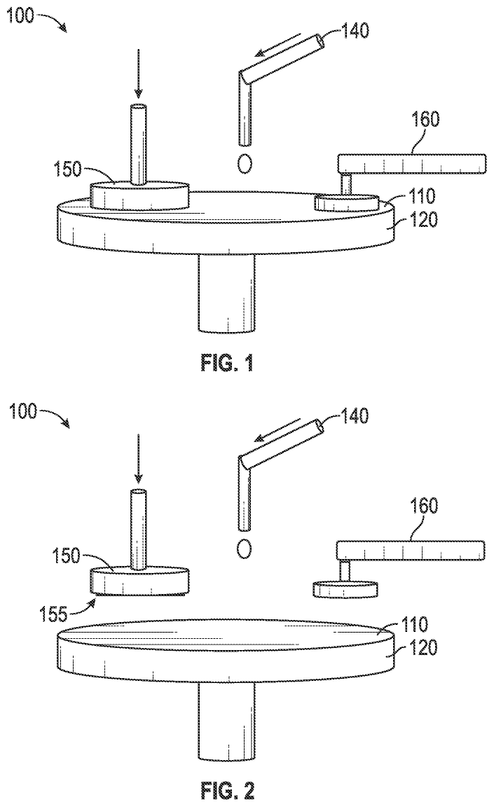

FIG. 2 is a view of the chemical mechanical planarization system of FIG. 1, showing a substrate 155 held by the substrate carrier 150 in a loading (e.g., upper) position. The substrate 155 can be held, for example, by force of a vacuum. Referring to both FIGS. 1 and 2, system 100 can include a slurry delivery system 140 configured to deliver the processing slurry to the substrate 155, and allow it to be chemically/mechanically planarized against the polishing pad 110. System 100 can include a pad conditioning arm 160, which includes a pad conditioner at its end, which can be configured to treat or “refresh” the surface roughness, or other processing characteristics of the pad, during or between processing cycles.

In the system 100 of FIGS. 1 and 2, polishing pad 110 is on the top surface of platen 120 which rotates counterclockwise about a vertical axis. Other orientations and directions of movement can be implemented.

The slurry delivery system 140 can deliver a slurry containing abrasive and corrosive particles to a surface of the treated polishing pad 130. The polishing slurries are typically colloidal suspensions of abrasive particles, e.g., colloidal silica, colloidal alumina, or colloidal ceria, in a water based medium. In various embodiments, the slurry delivery system 140 includes a metering pump, mass-flow-control regulator system, or other suitable fluid delivery components.

The substrate carrier 150 can hold substrate 155, for example, with a vacuum, so that the surface of the substrate 155 to be polished faces towards polishing pad 110. Abrasive particles and corrosive chemicals in the slurry deposited by the slurry delivery system 140 on the polishing pad 110 mechanically and chemically polish the substrate through abrasion and corrosion, respectively. The substrate carrier 155 and polishing pad 110 can move relative to each other in any of a number of different ways, to provide the polishing. For example, the substrate carrier 150 can apply a downward force against the platen 120 so that the substrate 155 is pressed against the polishing pad 110. The substrate 155 can be pressed against the polishing pad 110 with a pressurized membrane (not shown), as will be described further herein. Abrasive particles and corrosive chemicals of the slurry between the substrate 155 and the polishing pad 110 can provide chemical and mechanical polishing as the polishing pad 110 and substrate carrier 155 move relative to each other. The relative motion between polishing pads and substrate carriers can be configured in various ways, and either or both can be configured to oscillate, move linearly, and/or rotate, counterclockwise and/or clockwise relative to each other.

Pad conditioning arm 160 can condition the surface of polishing pad 110, by pressing against polishing pad 110 with a force, with relative movement therebetween, such as the relative motion described above with respect to the polishing pad and substrate carrier 150. The pad conditioning arm 160 in the illustrated embodiment can oscillate, with a rotating pad conditioner at its end, which contacts the polishing pad 110.

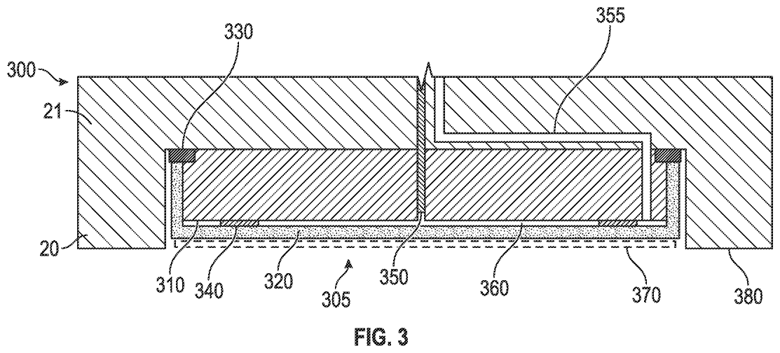

FIG. 3 is a partial cross-sectional view of a substrate carrier head 300 which may be included as a part of the substrate carrier 150 illustrated in FIGS. 1 and 2. The substrate carrier head 300 includes a membrane assembly 305 for a chemical mechanical planarization (CMP) system. In some embodiments, the substrate carrier head 300 (also referred to herein as a carrier head or simply carrier) may include a support base 380 to which the membrane assembly 305 is mounted. The support base 380 can be any suitable configuration to provide support to the membrane assembly. The support base 380 can attach and interface the remainder of the substrate carrier head 300 with a CMP system (not shown). The support base 380 can include a carrier body, substrate retainer, a support plate, and/or other components described elsewhere herein to support the wafer (e.g., membrane assembly 305) and/or interface the remainder of the carrier head 300 with a CMP system. The support base 380 can also form an aperture into which the membrane 320 can be placed to be held by the substrate carrier head 300.

The membrane assembly 305 may include a support plate 310, a resilient membrane 320, a membrane retainer, such as a membrane clamp 330, and an optional outer pressure ring 340, as shown. The support plate 310 can be any suitable configuration to support a wafer during processing, e.g., attach membrane assembly 305 to support base 380. For example, the support plate 310 may be mounted to the support base 380 using one or more bolts or other suitable attachment elements. The support plate 310 may be mounted to the support base 380 at various locations, such as along the outer perimeter of the support base 380.

The support plate 310 can be any suitable configuration to support a wafer, e.g., through the resilient membrane 320. The resilient membrane 320 may be secured to the support plate 310 in a number of different ways. The resilient membrane 320 may be secured to the support plate 310 before or after the support plate 310 is secured to the support base 380. The resilient membrane 320 may be secured to the support plate 310 through use of any of a number of suitable different membrane retainer holding elements, such as the membrane clamp 330. In some embodiments, the membrane clamp 330 may be spring loaded. In other embodiments, the membrane clamp 330 may tighten securely through the use of a fastening mechanism (e.g., nuts and bolts, etc.). The membrane clamp 330 can secure an outer portion (e.g., outer edge) of the membrane 320 to a corresponding portion of the support plate 310 and/or support base 380. The membrane retainer can be any suitable configuration to secure at least a portion of the membrane 320 to the support plate 310 and/or support base 380.

The resilient membrane 320 can be secured to the support plate 310 such that the membrane 320 can hold a substrate 370 against a polishing pad and process the substrate, for example, as described above with reference to FIGS. 1 and 2. The membrane can include a first surface (e.g., downwardly facing) configured to contact a surface (e.g., upwardly facing) of a substrate. The membrane 320 can be sufficiently resilient and flexible, such that in combination with the polishing pad materials and process parameters, the membrane 320 can apply a more uniform pressure across the entire substrate 370. In some embodiments, the resiliency and flexibility of the membrane 320 may also aid in reducing substrate breakage. The support plate 310 can be spaced from the membrane 320, to form a gap or membrane cavity 360 therebetween. In some embodiments, the membrane cavity 360 can be formed when the membrane 320 is in a quiescent (e.g., non-pressurized) state. The membrane cavity 360 can be supplied with a fluid, which can be pressurized to press the membrane 320 against the substrate 370 during planarization. For example, membrane 320 can be configured to allow the fluid to be in contact with a second surface of the membrane 320, e.g., an upwardly facing surface, opposing the aforementioned first membrane surface. Depending on the embodiment, the fluid can include a gas and/or a liquid. For example, a gas can be used to provide static pressure to the second surface of the membrane 330. In another application, a liquid can be used to provide pressure while also flowing along the membrane 330, while also flowing across the membrane to heat or cool the membrane 330.

The membrane cavity 360 can be sealed. In some embodiments, a fluid tight seal can be formed within the membrane cavity 360 to prevent the fluid from leaking out of the membrane cavity 360 when the fluid is pressurized. Thus, the membrane cavity 360 can form a fluid cavity. A seal can be formed between a portion of the membrane 320 and a portion of the carrier body (e.g., plate 310 and/or base 380), for example, at the membrane clamp 330. As used herein, a sealed membrane cavity encompasses a membrane cavity that is in fluid communication with inlet(s) and/or outlet(s) that can be selectively sealed (e.g., opened and closed, for example, with a valve).

In some embodiments, a portion of the membrane 320, such as an upper facing surface thereof, rests upon or is proximate to a corresponding portion of the plate 310, such as a lower facing surface thereof, when the membrane 320 is in a quiescent state, and the membrane cavity 360 is formed when the membrane 320 is expanded (e.g., pressurized via the fluid). The membrane cavity 360 can redistribute and account for variations in the fluid pressure against the membrane 320, and thus, against the substrate 370, during planarization. The fluid can be provided to the backside of the membrane 320 into the membrane cavity 360 through an inlet 350, as shown. The inlet 350 may be disposed within the support plate 310, or can supply fluid through other configurations. In some embodiments, vacuum can be provided to the cavity 360 through an inlet and/or outlet, for retaining a wafer 370 to the underside of the membrane assembly, as described further herein.

In some embodiments, the membrane cavity 360 can be formed by spacing the membrane 320 from the support plate 310. For example, the support plate 310 can include a recessed inner portion to form a cavity. In the illustrated embodiment, the membrane assembly 305 can include an optional outer pressure ring 340 to form the membrane cavity 360. In other embodiments, the membrane assembly 305 may be assembled without pressure rings. For example, the resilient membrane 320 may rest directly against the support plate 310 without a membrane cavity 360 separating the membrane 320 from the support plate 310, for example, when no fluid is present in the membrane cavity 360. In some embodiments, the membrane assembly 305 may include one or more pressure rings 340 arranged in concentric circles.

In another embodiment, the wafer carrier can comprise a multi-zone carrier. For example, the membrane 320 may be a multi-zoned membrane. Each zone in a multi-zone membrane can include a corresponding membrane cavity configured to receive a fluid, and/or be similarly (e.g., separately) controlled, as described herein for a single zone carrier with a single zone cavity. For example, the membrane 320 may have grooves (e.g., indentations) and/or raised portions of the membrane 320 that effectively segregate various zones of the membrane 320. In a non-limiting example, the grooves may be arranged in a series of concentric circles originating from the center of the membrane. In another example, the grooves and raise portions may be irregularly shaped (e.g., interconnecting circles, non-circular indentations, circular patterns scattered across the surface of the membrane) in order to improve distribution of pressure applied across the substrate 370 when attached to the membrane assembly 305. In some embodiments, the system may apply different pressures to one or more of the zones in a multi-zoned membrane to tune the removal rate in each of the zones. For example, the rate of removal may be higher for a zone in which higher pressure is applied.

The membrane 320 may be flexible such that it conforms to a structure that it surrounds. In some instances, the membrane 320 may be convex. For example, the membrane 320 may sag in the center. The membrane 320 may even be shaped like a cone such that a small area of the membrane 320 would be in contact with the substrate surface for finer precision polishing.

The membrane material may be any resilient material suitable for planarization, as described herein, and for use, for example, within a carrier head for a CMP process. In some embodiments, the membrane material may be one of rubber or a synthetic rubber material. The membrane material may also be one of Ethylene propylene diene monomer (M-class) (EPDM) rubber or silicone. Alternatively, it may be one or more combinations of vinyl, rubber, silicone rubber, synthetic rubber, nitrile, thermoplastic elastomer, fluorelastomers, hydrated acrylonitrile butadiene rubber, or urethane and polyurethane formas. In order to effectively cool (or heat, or otherwise control temperature of) the substrate, in certain embodiments, the material for the resilient membrane 320 may be selected based on the material's heat transfer properties. Thus, materials having higher thermal conductivity may be desirable when cooling a substrate, such as a silicon carbine substrate. For example, in some embodiments, the membrane material may be an elastomer, such as silicone, including those available under the trademark Arlon® owned by Rogers Corporation, which have thermal conductivities that can aid in cooling a substrate. In some embodiments, the resilient membrane 320 may include inorganic additives that increase the thermal conductivity of the resilient membrane 320 to improve the heat transfer between a temperature control fluid and the substrate. Examples of inorganic additives that increase thermal conductivity may include the series of additives manufactured under the trademark Martoxid®, owned by Martinswerk GMBH.

One or more membrane assemblies can be implemented within a single CMP system. The CMP system may have controls utilizing feedback from the system while operating to more accurately control the CMP process (e.g., variable speed motor controls, etc.).

In an exemplary embodiment, the membrane 320 may be planarized. For example, the membrane 320 can be made flat within a desired tolerance, and/or made to conform to a surface roughness within a desired tolerance. For example, the membrane 320 may undergo a planarization procedure wherein the membrane is subjected to a polishing pad. In addition, the membrane 320 may be introduced to a chemical slurry that causes the membrane 320 to become planarized. Furthermore, the surface roughness of the membrane 320 can be improved throughout this planarization process. Surface roughness can be important for membranes used within the context of a CMP process for at least two reasons: sealing and stiction. Through the planarization process, the surface roughness may be lowered in order to provide improved sealing between the substrate 370 and the membrane 320 for handling purposes. At the same time, the surface roughness may be increased in order to prevent stiction (i.e., the substrate sticking to the membrane from surface tension), and improve substrate release from the membrane after processing. Control mechanisms may be used during the planarization process (described below) in order to achieve a desired balance between low and high surface roughness. The control mechanism may be external to the device used to planarize the membrane.

### Example CMP Systems Configured to Planarize Substrates Having Flats or Voids

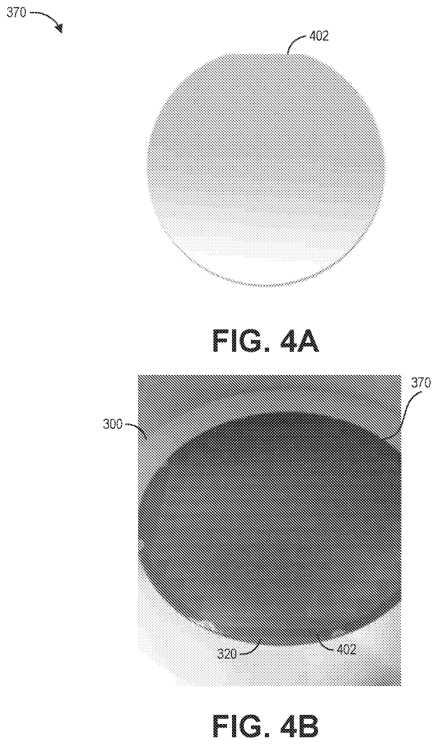

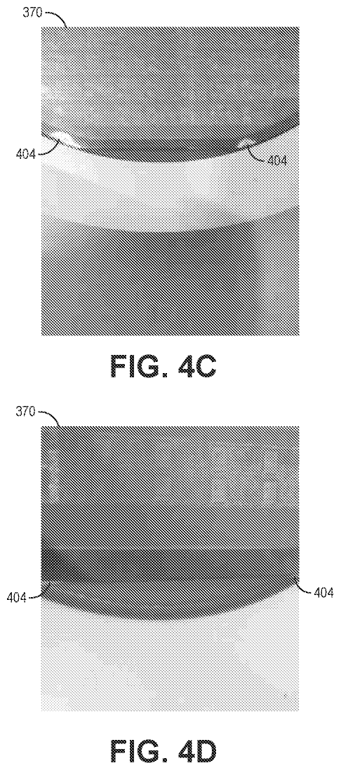

Many wafers may have one or more “flat(s)” or “void(s)” formed along an edge of the wafer. FIGS. 4A-4D illustrate an embodiment of a wafer 370 which can experience uneven planarization in accordance with aspects of this disclosure. In particular, FIG. 4A illustrates an embodiment of a wafer 370 in accordance with aspects of this disclosure. FIG. 4B illustrates a carrier 300 configured to hold the wafer 370. FIGS. 4C and 4D provide close up views of a portion of the wafer 370 having uneven planarization.

Because wafers may be substantially circular, as shown in FIG. 4A a wafer 370 can have a flat 402 edge that can provide a reference edge that provides a mechanical indication of the orientation of the crystal structure of the silicon on the wafer 370. For example, the flat 402 may form a fiducial that is aligned with the crystal structure of the silicon on the wafer. In contrast, for a circular wafer that does not include a flat 402 or other distinguishing characteristics in its shape, it may be difficult to determine the orientation of silicon crystal structure of the wafer due to its angular symmetry. Thus, the flat 402 can help provide a distinguishing feature that enables the orientation of the wafer to be visibly determined.

In some implementations, the wafer 370 can include a primary flat 402 and a secondary flat (not illustrated). Aspects of this disclosure can apply to improving the planarizing of wafers 370 including one or more flats 402.

When planarizing a wafer 370 having a flat 402 using a CMP system, one problem which can arise is a phenomenon called “Burning the Flat.” Burning the Flat generally refers to a very high removal rate in portions of the flat 402 area of the wafer 370 due to the void in the carrier 300. FIG. 4B illustrates a wafer 370 being held by a carrier 300 after planarization. For example, the wafer 370 may be held within an aperture formed in the substrate carrier head 300. A membrane 320 (e.g., such as the membrane 320 of FIG. 3) is visible in the void formed by the flat 402 in the wafer 370. FIGS. 4C and 4D illustrate portions 404 of the wafer 370 which may have experienced a higher removal rate than other portions 404 of the wafer 370 due to the flat 402.

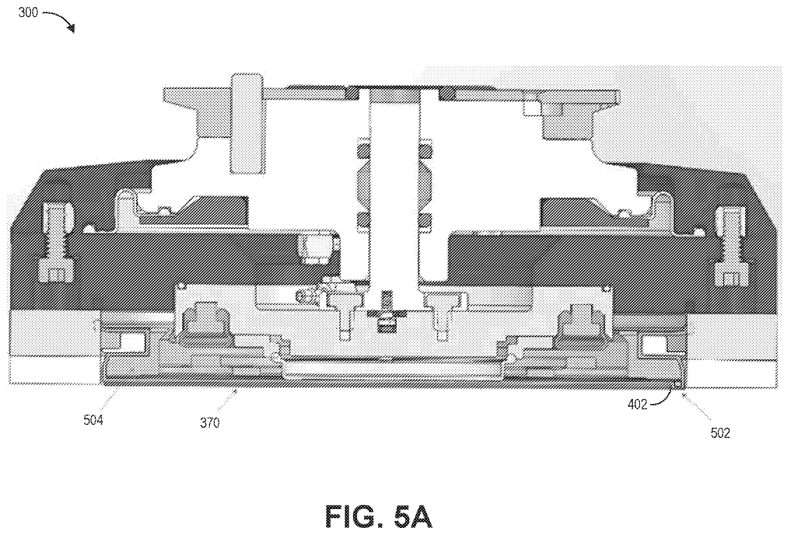

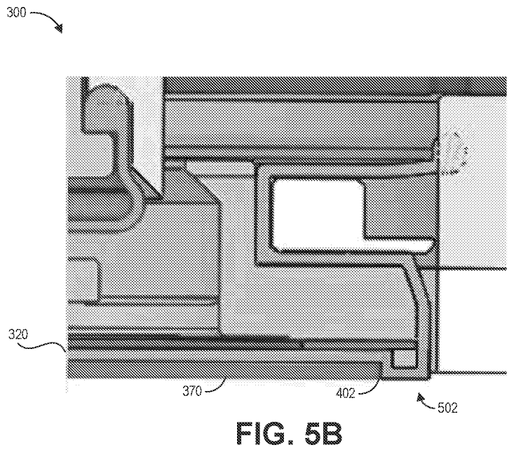

FIG. 5A provides a cross-section of the carrier 300 and wafer 370 to illustrate the membrane 320 filling a void 502 created by the flat 402 of the wafer 370 in accordance with aspects of this disclosure. FIG. 5B is a close up view of the area surrounding the void 502 shown in FIG. 5A.

With reference to FIGS. SA and SB, the substrate carrier head 300 holds the wafer 370 adjacent to the membrane 320. The flat 402 in the wafer 370 can be positioned adjacent to an outer most zone of the substrate carrier head 300, which can be referred to as the inner tube (IT) zone 504 (also referred to as a secondary zone). The flat 402 in the wafer 370 forms the void 502 and the membrane 320 fills the void 502 due to the pressure applied to the membrane 320 via the membrane cavity 360 (see FIG. 3). When the membrane 320 fills the void, additional pressure is applied to the wafer 370 near the flat 402. In addition, the membrane 320 rolls over the edge of the wafer 370 at the flat 402 and removes portions 404 of the wafer 370 in that area at a different (higher) rate than the rest of the wafer 370.

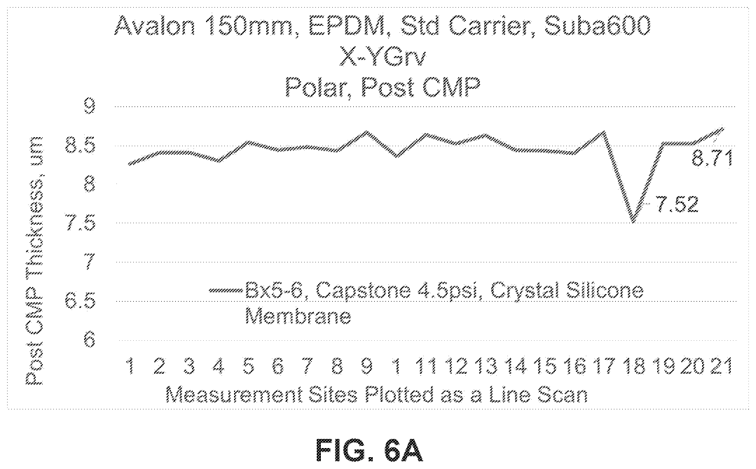

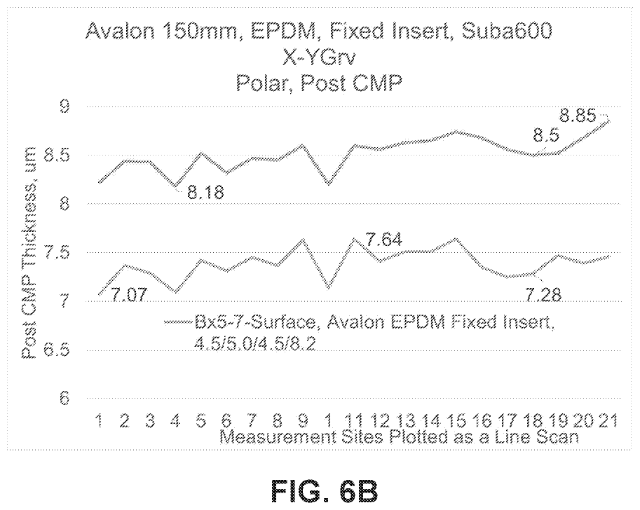

FIG. 6A shows process results with the effects seen in the large range numbers in non-uniformity due to the burning the flat phenomenon. FIG. 6B shows the range numbers for the process results when the effects of burning the flat are reduced or eliminated.

One technique for reducing or eliminating membrane roll is to prevent air pressure from filling the void 502 at the flat 402 area. As discussed above, the flat 402 can be located below the IT zone 504. In certain implementations, the membrane 320 can be wrapped around the IT zone 504, providing a substantially continuous contact surface across the wafer 370. This feature can provide good process results outside of the flat 402 area.

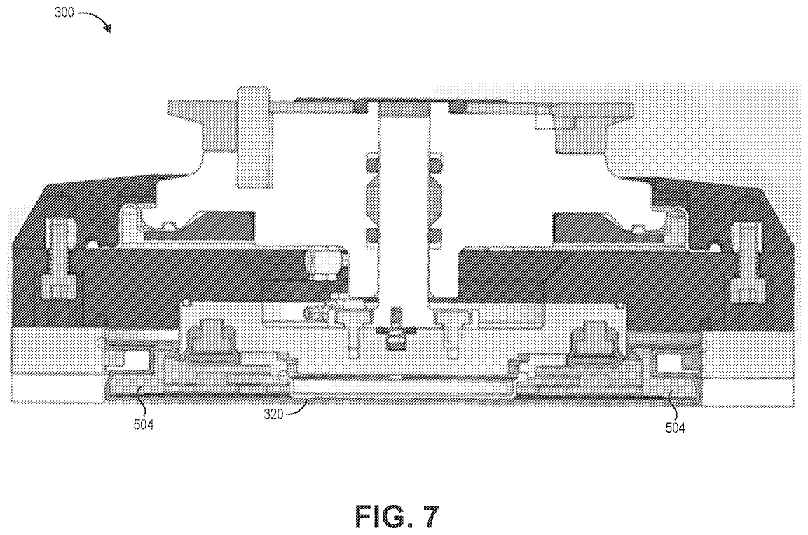

FIG. 7 provide another view of the substrate carrier head 300 including the membrane 320 and the IT zone 504. The substrate carrier head 300 of FIG. 7 can provide substantially a continuous contact surface between the membrane 320 and the wafer 370 (not shown in FIG. 7).

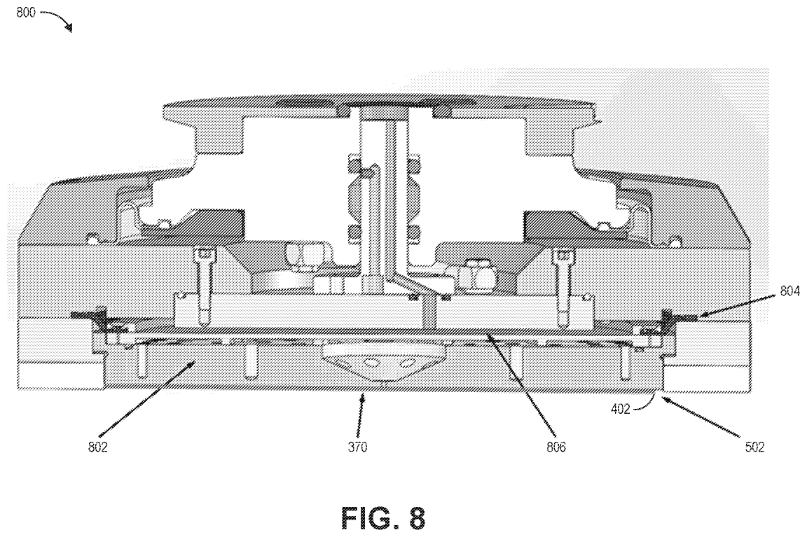

Another technique for reducing or eliminating membrane roll is to use a rigid back carrier in place of a membrane 320. FIG. 8 is a cross-sectional view of a rigid back style substrate carrier head 800 in accordance with aspects of this disclosure. The substrate carrier head 800 includes a rigid wafer backer plate 802 configured to hold a wafer 370 having a flat 402, and a chamber flexible membrane seal 804. The substrate carrier head 800 is configured to provide a pressure/vacuum 806 which pushes or pulls the rigid wafer backer plate 802. The substrate carrier head 800 can at least partially address the flat burning issue since there is no membrane 320 to fill the void 502 formed by the flat 402. However, one drawback to this approach is that such rigid back carrier systems are designed for only rigid back carriers and cannot be modified for other uses (e.g., to include a membrane based carrier or a hybrid carrier).

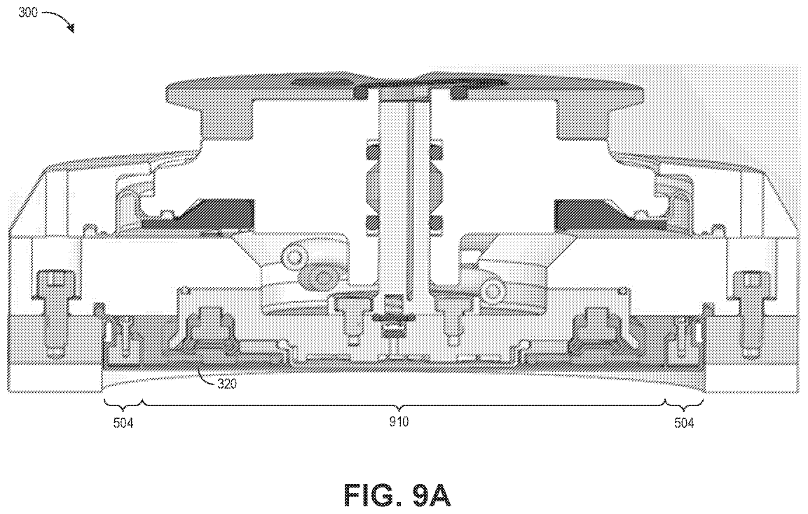

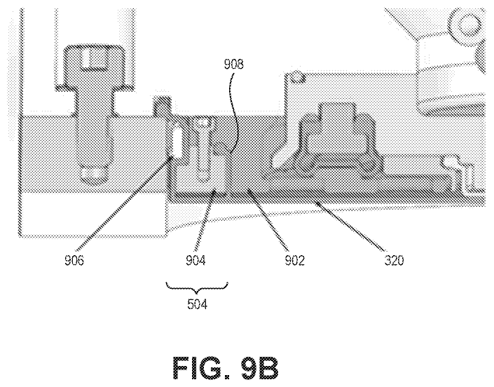

Aspects of this disclosure are configured to address one or more of the above-discussed drawbacks using a single piece two-zone control membrane. FIGS. 9A and 9B illustrate a substrate carrier head 300 having a sealed IT zone 504 in accordance with aspects of this disclosure. Specifically, FIG. 9A provides a cross-sectional view of the substrate carrier head 300 while FIG. 9B provides a close up view of the IT zone 504.

With reference to FIGS. 9A and 9B, the substrate carrier head 300 includes an inner IT plate 902, an outer IT plate 904, and a membrane backing ring 906. The membrane 320 is held in place by the inner IT plate 902, the outer IT plate 904, and the membrane backing ring 906. In particular, an internal ridge 908 of the membrane 320 extends between the inner IT plate 902 and the outer IT plate 904 and is secured therebetween. The internal ridge 908 can be formed as a ring that separates the IT zone 504 from a primary zone 910 of the membrane 320. The internal ridge 908 can provide a seal between the inner IT plate 902 and the outer IT plate 904, thereby sealing the primary zone 910 from the IT zone 504. That is, the internal ridge 908 can be configured to seal the membrane cavity 360 such that pressure applied within the membrane cavity 360 is applied to the primary zone 910 and is not applied to the portion of the membrane 320 outside of the internal ridge 908 forming the IT zone 504. The membrane 320 continues past the internal ridge 908 to wrap around the outer IT plate 904 and is secured in place via the membrane backing ring 906. In some embodiments, IT zone 504 may have a width that is larger than the width of the void 502, thereby preventing the membrane 320 from filling the void 502.

By sealing off the membrane cavity 360 from the edge of the IT zone 504 using the internal ridge 908, the portion of the membrane 320 supported by the outer IT plate 904 can be prevented from inflating into to the void 502 formed by the flat 402. Since the membrane 320 can be prevented from inflating into the void 502, this configuration can reduce or eliminate flat burn. In addition, the outer IT plate 904 can have an annular shape that overlaps the IT zone 504. Thus, the outer IT plate 904 can provide mechanical support to the portion of the membrane 320 formed in the IT zone 504, thereby reducing or preventing pressurization, inflation, and/or bulging of the membrane 320 in the void 502. Accordingly, the outer IT plate 904 can help reduce and/or eliminate wafer burn.

In addition, the membrane 320 can still be configured for substantially continuous contact across substantially the entire wafer surface while maintaining separation between the two zones. Using this design, the process for controlling the membrane 320 zones (e.g., providing pressure via the membrane cavity 360) can be substantially the same as other CMP systems, while also providing for isolation of the void 502/flat 402 area to prevent flat burn. Although not illustrated, the primary zone 910 can be divided into a plurality of sub-zones, each of which can be independently pressured, for example, via a corresponding membrane cavity 360. The substrate carrier head 300 can include a processor (which may be located in another portion of the CMP system) configured to control the pressure applied to each of the sub-zones.

Embodiment of this disclosure provide a control membrane (e.g., membrane 320) which can be formed as a single piece with two or more control zones, including a primary zone 910 and an IT zone 504 (or secondary zone). By isolating the primary zone 910 from the IT zone 504, the substrate carrier head 300 is able to provide substantially continuous contact between the membrane 320 and the wafer 370, while also enabling separate zone control (e.g., applying different pressures to the membrane 320 in the primary zone 910 and the IT zone 504). Moreover, the annular outer IT plate 904 can provide a rigid, mechanical support to the portion of the membrane 320 in the IT zone 504, enabling this portion of the membrane 320 to be supported without the use of pneumatic pressure. In addition, the outer IT plate 904 can also provide substantially continuous contact between the portion of the membrane 320 in the IT zone 504 and the wafer 370 while also providing support in this region. The outer IT plate 904 is also configured to provide and control the pressure applied to the membrane 320 in the IT zone 504, which is in turn applied to the corresponding portion of the wafer 370. By replacing pneumatic pressure with mechanical support, the portion of the membrane 320 in the IT zone 504 can be prevented inflating into the void 502. Accordingly, the substrate carrier head 300 is able to reduce or eliminate the high removal rate at the void 502 area of the wafer 370 due to the asymmetric pressure caused by membrane roll.

Moreover, by isolating the pressures applied to the primary zone 910 and the IT zone 504 as described herein, the pressurization, inflation, and bulging of the membrane 320 in the IT zone 504 can be prevented. This can reduce pressure applied to the flat 402 area of the wafer 370.

In some embodiments, the membrane backing ring 906 can be divided into two or more pieces which can be attached using fasteners to form a continuous ring. For example, the membrane backing ring 906 may include two semi-circular pieces in certain implementations. By forming the membrane backing ring 906 with multiple pieces that can be assembled into the membrane backing ring 906, the assembly of the substrate carrier head 300 including attaching the membrane 320 to the membrane backing ring 906, can be simplified. This can make assembly of the substrate carrier head 300 easier as well as simplify tensioning of the membrane 320.

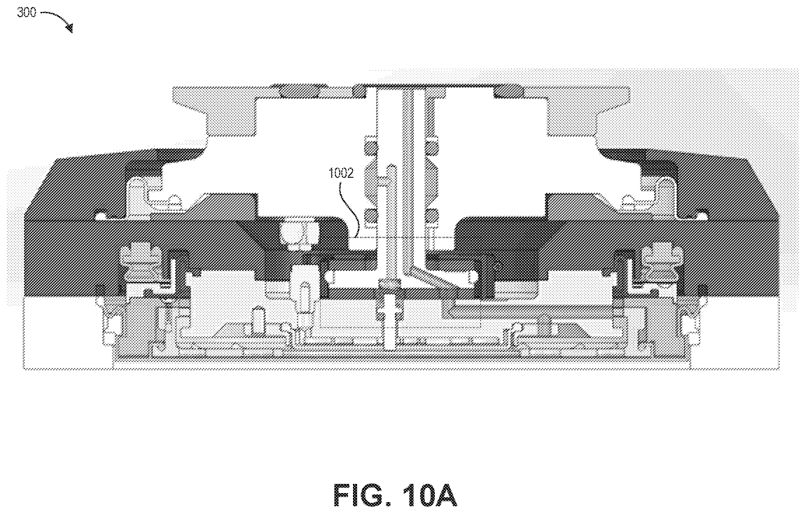

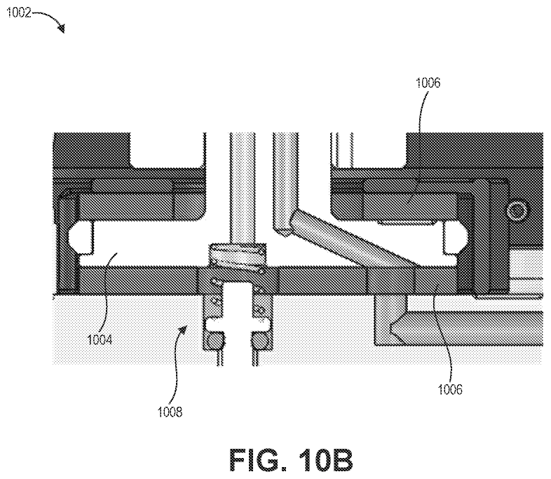

FIGS. 10A and 10B illustrate a substrate carrier head 300 having a gimbaling apparatus 1002 in accordance with aspects of this disclosure. In particular, FIG. 10A provides a cross-sectional view of the substrate carrier head 300 having the gimbaling apparatus 1002 while FIG. 10B provides a close up view of the gimbaling apparatus 1002.

With reference to FIGS. 10A and 10B, the gimbaling apparatus 1002 includes a rigid shaft 1004, compliant material 1006, and a gimbaled section 1008. In general, a gimbaling apparatus can enable a body to incline freely in any direction or suspend the body so that the body will remain level when its support is tipped. In the context of the substrate carrier head 300, the gimbaling apparatus 1002 is configured to enable the substrate carrier head 300 to incline freely in any direction or suspend the substrate carrier head 300 so that the substrate carrier head 300 will remain level when the rigid shaft 1004 is tipped.

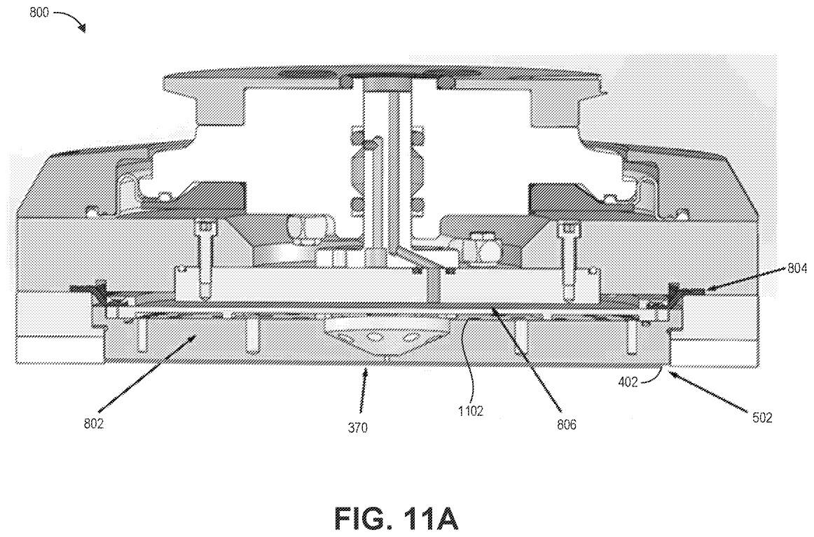

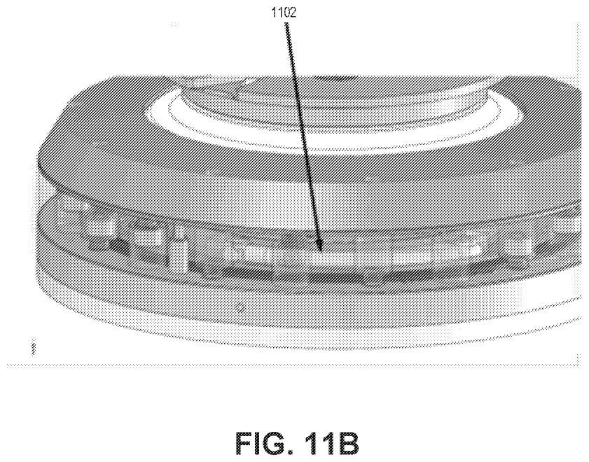

FIGS. 11A and 11B illustrates another embodiment of a substrate carrier head 800 according to aspects of this disclosure. FIG. 11A illustrates a cross-section of the substrate carrier head 800 and FIG. 11B provides a perspective view of the substrate carrier head 800.

The substrate carrier head 800 of FIGS. 11A and 11B is embodied as a hybrid membrane controlled rigid back carrier. The substrate carrier head 800 includes a includes a rigid wafer backer plate 802 configured to hold a wafer 370 having a flat 402, and a chamber flexible membrane seal 804. The substrate carrier head 800 is configured to provide a pressure/vacuum 806 which pushes or pulls the rigid wafer backer plate 802. The substrate carrier head 800 also includes a plurality of vacuum through holes which are coupled to a wafer chucking vacuum manifold and pluming 1102.

Advantageously, the substrate carrier head 800 can directly replace a membrane-based carrier head and can be run on membrane carrier-based CMP systems. For example, compatible system include the Axus Surface™, Applied Material Mirra™ and others. Standard rigid back carrier from Strausbaugh Viprr™, Speedfam/IPEC Rigidback and others cannot be run on these membrane systems, which are most of the CMP systems in the world.

One aspect of the substrate carrier head 800 is the integration of a membrane to control the pressure on the wafer compared to using a carrier hard mounted to the spindle or arm to control the wafer pressure.

In certain implementations, providing a substrate carrier head 800 with a hybrid membrane controlled rigid back carrier enables membrane pressure control while also reducing wafer burn due to the rigid back portion of the carrier in the IT zone 504. In some embodiments, the substrate carrier head 800 having a hybrid membrane controlled rigid back carrier can be compatible with a large number of membrane control CMP systems.

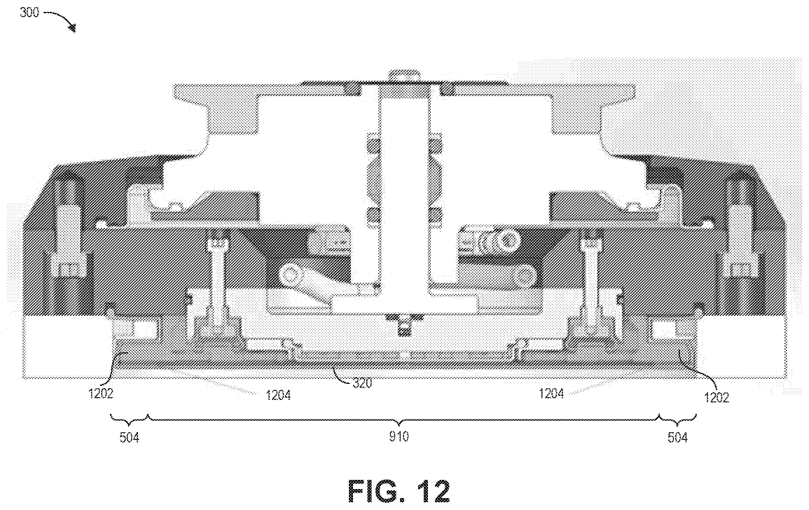

FIG. 12 is another embodiment of a substrate carrier head 300 according to aspects of this disclosure. With reference to FIG. 12, the substrate carrier head 300 includes a membrane 320 which includes a primary zone 910 and an IT zone 504. In contrast to the embodiment of FIGS. 9A and 9B, the membrane of FIG. 12 can be attached to an IT plate 1202 via an adhesive 1204. The adhesive 1204 attaches (or adheres) the membrane 320 to the underlying and IT plate 1202, thus constraining the membrane 320 in the area where the adhesive 1204 bonds the membrane 320 to the IT plate 1202.

That is, the adhesive 1204 prevents any pressure applied to the 360 from being applied to the IT zone 504 of the membrane 320, while still enabling the pressure to be applied to the primary zone 910 of the membrane 320. Thus, by preventing the IT zone 504 of the membrane 320 from expanding into a void 502 formed by the flat 402, the substrate carrier head 300 can help reduce or eliminate wafer burn.

Depending on the implementation, the IT plate 1202 can include various methods and means for such adhesion and/or bonding including the application of various adhesive materials. For example, the adhesive materials can include one or more of: glue, epoxy, chemical, thermal, molding, vulcanization, etc.

As described herein, by preventing the pressure applied to the primary zone 910 of the membrane 320 from reaching the IT zone 504, for example, by using a pressure barrier, isolation, and/or constraint (e.g. via adhesive contact layer), pressurization, inflation, and bulging of the IT zone 504 can be reduced or prevented. This can reduce excess pressure from being applied to the flat 402 of a wafer 370, thereby reducing wafer burn. These techniques can be particularly advantageous when processing relatively hard materials (e.g., silicon carbide, sapphire, etc.) that may be processed using pressures that are higher than those for relatively softer materials.

### SUMMARY

The word “exemplary” is used herein to mean “serving as an example, instance, or illustration.” Any aspect or embodiment described herein as “exemplary” is not necessarily to be construed as preferred or advantageous over other aspects or embodiments. Various aspects of the novel systems, apparatuses, and methods are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the novel systems, apparatuses, and methods disclosed herein, whether implemented independently of, or combined with, any other aspect described. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosures set forth herein. It should be understood that any aspect disclosed herein may be embodied by one or more elements of a claim.

It should also be understood that, unless a term is expressly defined in this patent using the sentence “As used herein, the term ‘______’ is hereby defined to mean . . . ” or a similar sentence, there is no intent to limit the meaning of that term, either expressly or by implication, beyond its plain or ordinary meaning, and such term should not be interpreted to be limited in scope based on any statement made in any section of this patent (other than the language of the claims). To the extent that any term recited in the claims at the end of this patent is referred to in this patent in a manner consistent with a single meaning, that is done for sake of clarity only so as to not confuse the reader, and it is not intended that such claim term be limited, by implication or otherwise, to that single meaning.

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Conjunctive language such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5% of, within less than 1% of, within less than 0.1% of, and within less than 0.01% of the stated amount, depending on the desired function or desired result.

While certain embodiments have been described, these embodiments have been presented by way of example only, and are not intended to limit the scope of the disclosure. Indeed, the novel methods and systems described herein may be embodied in a variety of other forms. Furthermore, various omissions, substitutions and changes in the systems and methods described herein may be made without departing from the spirit of the disclosure. The accompanying claims and their equivalents are intended to cover such forms or modifications as would fall within the scope and spirit of the disclosure.

Features, materials, characteristics, or groups described in conjunction with a particular aspect, embodiment, or example are to be understood to be applicable to any other aspect, embodiment or example described in this section or elsewhere in this specification unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The protection is not restricted to the details of any foregoing embodiments. The protection extends to any novel one, or any novel combination, of the features disclosed in this specification (including any accompanying claims, abstract and drawings), or to any novel one, or any novel combination, of the steps of any method or process so disclosed.

Furthermore, certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a claimed combination can, in some cases, be excised from the combination, and the combination may be claimed as a subcombination or variation of a subcombination.

Moreover, while operations may be depicted in the drawings or described in the specification in a particular order, such operations need not be performed in the particular order shown or in sequential order, or that all operations be performed, to achieve desirable results. Other operations that are not depicted or described can be incorporated in the example methods and processes. For example, one or more additional operations can be performed before, after, simultaneously, or between any of the described operations. Further, the operations may be rearranged or reordered in other implementations. Those skilled in the art will appreciate that in some embodiments, the actual steps taken in the processes illustrated and/or disclosed may differ from those shown in the figures. Depending on the embodiment, certain of the steps described above may be removed, others may be added. Furthermore, the features and attributes of the specific embodiments disclosed above may be combined in different ways to form additional embodiments, all of which fall within the scope of the present disclosure. Also, the separation of various system components in the implementations described above should not be understood as requiring such separation in all implementations, and it should be understood that the described components and systems can generally be integrated together in a single product or packaged into multiple products. For example, any of the components for an energy storage system described herein can be provided separately, or integrated together (e.g., packaged together, or attached together) to form an energy storage system.

For purposes of this disclosure, certain aspects, advantages, and novel features are described herein. Not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

The headings provided herein, if any, are for convenience only and do not necessarily affect the scope or meaning of the devices and methods disclosed herein.

The scope of the present disclosure is not intended to be limited by the specific disclosures of preferred embodiments in this section or elsewhere in this specification, and may be defined by claims as presented in this section or elsewhere in this specification or as presented in the future. The language of the claims is to be interpreted broadly based on the language employed in the claims and not limited to the examples described in the present specification or during the prosecution of the application, which examples are to be construed as non-exclusive.

What is claimed is:

1. A substrate carrier head for a chemical mechanical planarization (CMP) system, comprising:
a carrier body comprising an aperture configured to receive a wafer;
a membrane having a first surface configured to contact a surface of the wafer and a second surface opposing the first surface, the membrane having a primary zone and a secondary zone;
a membrane cavity formed along the second surface and configured to apply pressure to the membrane within the primary zone; and
a membrane support plate configured to support the secondary zone of the membrane.

2. The substrate carrier head of claim 1, wherein the secondary zone of the membrane is isolated from the pressure applied to the primary zone of the membrane.

3. The substrate carrier head of claim 1, wherein the membrane is further configured for substantially continuous contact with the wafer.

4. The substrate carrier head of claim 1, wherein the primary zone of the membrane comprises a plurality of sub-zones, the substrate carrier head further comprising a processor configured to control a pressure applied to each of the sub-zones independently.

5. The substrate carrier head of claim 1, wherein the wafer comprises a flat edge that forms a void when the wafer is held by the carrier body, wherein a width of the secondary zone is larger than the void to prevent the membrane from filling the void.

6. The substrate carrier head of claim 1, wherein the membrane support plate has an annular shape and is configured to control pressure applied to the secondary zone of the membrane.

7. The substrate carrier head of claim 6, wherein the substrate carrier head is compatible with a membrane control CMP System.

8. The substrate carrier head of claim 1, further comprising:
an inner plate; and
an outer plate,
wherein the membrane further comprises an internal ridge secured between the inner plate and the outer plate and configured to isolate the primary zone from the secondary zone.

9. The substrate carrier head of claim 8, further comprising:
a membrane backing ring arranged above the outer plate and securing the membrane in place.

10. The substrate carrier head of claim 1, further comprising:
an adhesive that adheres the secondary zone of the membrane to the membrane support plate.

11. A chemical mechanical planarization (CMP) system, comprising:
a substrate carrier head, comprising:
a carrier body comprising an aperture configured to receive a wafer;
a membrane having a first surface configured to contact a surface of the wafer and a second surface opposing the first surface, the membrane having a primary zone and a secondary zone;
a membrane cavity formed along the second surface and configured to apply pressure to the membrane within the primary zone; and
a membrane support plate configured to support the secondary zone of the membrane; and
a processor configured to control pressure applied to the membrane via the membrane cavity.

12. The CMP system of claim 11, wherein the secondary zone of the membrane is isolated from the pressure applied to the primary zone of the membrane.

13. The CMP system of claim 11, wherein the membrane is further configured for substantially continuous contact with the wafer.

14. The CMP system of claim 11, wherein the primary zone of the membrane comprises a plurality of sub-zones, the substrate carrier head further comprising a processor configured to control a pressure applied to each of the sub-zones independently.

15. The CMP system of claim 11, wherein the wafer comprises a flat edge that forms a void when the wafer is held by the carrier body, wherein a width of the secondary zone is larger than the void to prevent the membrane from filling the void.

16. The CMP system of claim 11, wherein the membrane support plate has an annular shape and is configured to control pressure applied to the secondary zone of the membrane.

17. The CMP system of claim 16, wherein the substrate carrier head is compatible with a membrane control CMP System.

18. The CMP system of claim 11, wherein the substrate carrier head further comprises:
an inner plate; and
an outer plate,
wherein the membrane further comprises an internal ridge secured between the inner plate and the outer plate and configured to isolate the primary zone from the secondary zone.

19. The CMP system of claim 18, wherein the substrate carrier head further comprises:
a membrane backing ring arranged above the outer plate and securing the membrane in place.

20. The CMP system of claim 11, wherein the substrate carrier head further comprises:
an adhesive that adheres the secondary zone of the membrane to the membrane support plate.

21. A method of isolating a primary zone of a membrane from a secondary zone of a membrane, comprising:
receiving a wafer in an aperture of a carrier body, the carrier body comprising a membrane having a first surface configured to contact a surface of the wafer and a second surface opposing the first surface, the membrane having a primary zone and a secondary zone;
applying pressure to the primary zone of the membrane via a membrane cavity formed along the second surface of the membrane; and
supporting the secondary zone of the membrane with a support plate.

22. The method of claim 21, further comprising:
isolating the secondary zone of the membrane from the pressure applied to the primary zone of the membrane.

23. The method of claim 21, wherein the membrane is further configured for substantially continuous contact with the wafer.
